(19) United States
(12) Patent Application Publication
(10) Pub. No.: US 2025/0073915 A1
(43) Pub. Date: Mar. 6, 2025

(54) SEMICONDUCTOR DEVICE TRANSPORT UNIT AND CHAMBER INCLUDING SEMICONDUCTOR DEVICE TRANSPORT UNIT FOR PERFORMING PROCESS FOR SEMICONDUCTOR DEVICE

(71) Applicant: ATECO INC., Gunpo-si (KR)

(72) Inventors: Taek Seon LEE, Hwaseong-si (KR); Ho Nam KIM, Seongnam-si (KR); Sung Chul MOON, Gunpo-si (KR); Dong Jun KIM, Siheung-si (KR)

(21) Appl. No.: 18/816,337

(22) Filed: Aug. 27, 2024

(30) Foreign Application Priority Data
Aug. 31, 2023 (KR) 10-2023-0115566

(51) Int. Cl. B25J 11/00; B25J 19/00; H01L 21/67; H01L 21/677

(52) U.S. Cl. CPC B25J 11/0095; B25J 19/00; H01L 21/67248; H01L 21/67742

(57) ABSTRACT

A semiconductor device transport unit according to an embodiment of the present disclosure may include a transport shaft disposed in an internal space formed by a chamber and extended along a transport direction of a semiconductor device, a moving holder mounted on the transport shaft with an allowable spacing and transporting a carrier having the semiconductor device loaded thereinto along the transport direction, and a temperature adjuster that adjusts a temperature of at least one of the moving holder and the transport shaft so that the moving holder is prevented from being fixed to the transport shaft in a temperature atmosphere.

### CROSS REFERENCE TO RELATED APPLICATION

This application is based on and claims priority under 35 U.S.C. § 119 to Korean Patent Application No. 10-2023-0115566 filed on Aug. 31, 2023 in the Korean Intellectual Property Office, the disclosure of which is incorporated by reference herein in its entirety.

### BACKGROUND

### Field

The present disclosure relates to a semiconductor device transport unit and a chamber including a semiconductor device transport unit for performing a process for a semiconductor device.

### Related Art

A device performance tester is a device that tests various devices after the devices are manufactured. This device performance tester artificially creates various environments for a connected device to test whether or not the device is operating normally. Examples of the semiconductor device may include various semiconductor elements such as a D-RAM, an S-RAM, an SO-DIMM, a U-DIMM, an LPCAMM, an SSD, and an HBM, semiconductor modules and electronic components, DIEs obtained by cutting a wafer, IC chips including DIEs in which integrated circuits are formed, and laminates using the DIEs. Here, the HBM (High Bandwidth Memory) is a high-performance memory formed by vertically stacking DRAM DIEs, and is formed so that DIEs on respective layers send or receive signals through electrodes, such as through silicon vias (TSVs), and micro bump structures.

Since the HBM has hundreds of fine pins or thousands or more fine pins and is very small in size, special care must be taken to load and transport the HBM. For example, since the HBM has a large number of fine pins even though the HBM is small in size, a high-difficulty fine pitch alignment is required for a test, and the HBM is vulnerable to damage due to contact.

Tested devices may be classified to a good product, a re-test, a bad product, and the like according to test results by a linked handler. Here, the handler may be a device that loads a number of packaged devices onto a device performance tester, separates the tested devices from the device performance tester, and then classifies the devices according to the results.

The tester can continuously perform the test through exchange between a tray having devices to be tested and a tray having tested devices using the handler.

Meanwhile, a type of device performance test is a temperature load test. The temperature load test is a test for checking whether or not a device satisfies required performance conditions under a specific temperature condition (a high or low temperature).

The temperature load test is performed in a state where an internal space of a test chamber for performing a test process is set to the specific temperature condition. The test chamber is set to maintain the temperature condition until a target number of devices have all been tested.

Further, a system that performs the temperature load test may include a soak chamber and/or a de-soak chamber in some cases. The soak chamber may be a chamber in which a semiconductor device exposed to a room temperature condition is aged to be exposed to a temperature atmosphere for the temperature load test. On the other hand, the de-soak chamber may be a chamber in which a semiconductor device for which the test has been completed is aged to return to an external environment.

Meanwhile, various components disposed inside chambers where a temperature atmosphere is changed for the test are required to be designed in consideration of an influence of temperature change. In particular, a transport unit that transports semiconductor devices, carriers having semiconductor devices loaded therein, or the like inside such chambers is required to be designed in consideration of, for example, thermal expansion, condensation, and/or frost so that the semiconductor devices can be transported under various temperature conditions.

### SUMMARY

An object of the present disclosure is to provide a transport unit for semiconductor devices capable of securing good transport performance even under various temperature conditions.

The objects of the present disclosure are not limited to the object described above, and other objects that are not described can be clearly understood by those skilled in the art from the description below.

A semiconductor device transport unit according to an embodiment of the present disclosure for achieving the object may include a transport shaft disposed in an internal space formed by the chamber and extended along a transport direction of the semiconductor device; a moving holder mounted on the transport shaft with an allowable spacing and configured to transport a carrier having the semiconductor device loaded thereinto along the transport direction; and a temperature adjuster configured to adjust a temperature of at least one of the moving holder and the transport shaft so that the moving holder is prevented from being fixed to the transport shaft in the temperature atmosphere.

The temperature adjuster may adjust the temperature of the moving holder and the transport shaft so that a degree of thermal deformation of the moving holder and the transport shaft due to the temperature atmosphere is reduced.

The temperature adjuster may include a heating wire formed to transfer heat to the transport shaft and extended by a predetermined length along the transport direction.

The heating wire may include one end part inserted into the transport shaft and extended by the predetermined length along the transport direction, and the other end part protruding to the outside of the transport shaft and connected to a control device.

The chamber may include a first gate configured to divide an external space from the internal space, and a second gate configured to divide the internal space from a space formed by an external chamber for performing a process for the semiconductor device.

The transport shaft may extend between the first gate and the second gate.

The other end part of the heating wire may protrude to the first gate from the transport shaft.

The temperature atmosphere may be set to a temperature equal to or lower than a room temperature, and the temperature adjuster may transfer heat to the transport shaft and the moving holder to prevent at least one of condensation and frost from being formed at the allowable spacing.

The moving holder may include a moving block having a through hole into which the transport shaft is inserted; and a ball installed inside the moving block to protrude into the through hole and configured to support the transport shaft at a position inside the through hole.

A plurality of the balls may protrude into the through hole to prevent the transport shaft from coming into contact with the moving block.

The moving holder may include a moving block configured to move forward and backward on the transport shaft; and a holding block formed under the moving block to be able to be raised or lowered with respect to the moving block and configured to hold the carrier.

The moving holder may further include a guide rail extended along a direction in which the transport shaft is extended, raised or lowered together with the holding block, and configured to support the holding block moving forward and backward along the moving block in a process in which the moving block moves forward and backward on the transport shaft.

The holding block may include a first holding frame having a hook which is protruding downward and inserted into a groove of the carrier in a lowered state, and a second holding frame formed that a spacing with the first holding frame is adjustable, and having another hook which is protruding downward and inserted into another groove of the carrier in a lowered state.

The carrier may load an HBM or a DIE forming the HBM as the semiconductor device, and include terminal electrically connected to the loaded semiconductor device.

A chamber for performing a process for a semiconductor device according to an embodiment of the present disclosure for achieving the object may include a chamber housing configured to form an internal space through which the semiconductor device passes; and a transport unit installed to transport the semiconductor device.

The transport unit may include a transport shaft disposed in the internal space and extended along a transport direction of the semiconductor device, a moving holder mounted on the transport shaft with an allowable spacing and configured to transport a carrier having the semiconductor device loaded thereinto along the transport direction; and a temperature adjuster configured to adjust a temperature of at least one of the moving holder and the transport shaft so that the moving holder is prevented from being fixed to the transport shaft in the temperature atmosphere.

Other specific details of the present disclosure are included in the detailed description and drawings.

According to the embodiments of the present disclosure, at least the following effects are provided.

It is possible to secure good transport performance under various temperature conditions.

The effects according to the present disclosure are not limited to the content exemplified above, and various effects are included in the present specification.

### BRIEF DESCRIPTION OF THE DRAWINGS

FIG. 1 is a conceptual drawing illustrating chambers to which a semiconductor device transport unit according to an embodiment of the present disclosure can be applied.

FIG. 2 is a diagram illustrating the semiconductor device transport unit according to the embodiment of the present disclosure.

FIG. 3 is a view illustrating the transport unit according to the embodiment of the present disclosure when viewed from a different angle than that in FIG. 2.

FIG. 4 is an enlarged view illustrating a moving holder portion in the transport unit according to the embodiment of the present disclosure.

FIG. 5 is a view illustrating a transport shaft and a moving block according to an embodiment of the present disclosure when viewed from the front.

FIG. 6 is a conceptual diagram illustrating an example in which the semiconductor device transport unit according to the embodiment of the present disclosure is installed inside a chamber.

FIG. 7 is a view partially illustrating a holding block and a test tray according to an embodiment of the present disclosure.

FIG. 8 is a view illustrating a case where the transport unit according to the embodiment of the present disclosure holds a test tray at an initial position.

FIG. 9 is a view illustrating a case where the transport unit according to the embodiment of the present disclosure transports the test tray to a target position.

### DESCRIPTION OF EXEMPLARY EMBODIMENTS

The advantages and characteristics of the present disclosure and methods for achieving these will become clear by referring to embodiments to be described in detail below together with the attached drawings. However, the present disclosure is not limited to the embodiments to be disclosed below, but can be implemented in various different forms, and the present embodiments are provided only to make the present disclosure complete and to fully inform those skilled in the art to which the present disclosure pertains of the scope of the disclosure, and the present disclosure is defined only by the scope of the claims.

Further, the embodiments described in the present specification will be described with reference to cross-sectional views and/or schematic views, which are ideal illustrative views of the present disclosure. Therefore, forms of the illustrative views may be modified due to, for example, manufacturing technologies and/or tolerances. Further, components in drawings illustrated in the present disclosure may be illustrated to be somewhat enlarged or reduced for convenience of description. The same components are denoted by the same reference signs throughout the specification.

Hereinafter, the present disclosure will be described with reference to the drawings illustrating a semiconductor device transport unit and a chamber including the semiconductor device transport unit for performing a process for a semiconductor device according to an embodiment of the present disclosure.

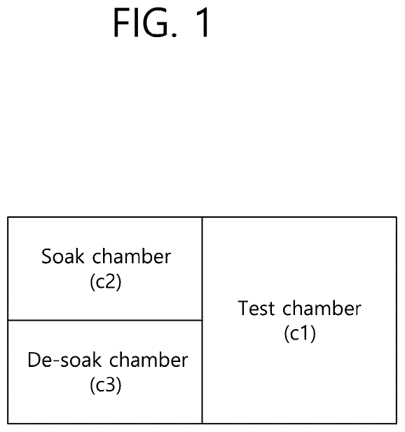

FIG. 1 is a diagram conceptually illustrating chambers to which a semiconductor device transport unit according to an embodiment of the present disclosure can be applied.

The semiconductor device transport unit according to the embodiment of the present disclosure can be applied to various chambers c1, c2, and c3 for performing a process for a semiconductor device. For example, the process for a semiconductor device may be a temperature load test for evaluating the performance of the semiconductor device. In this case, the semiconductor device transport unit according to the embodiment of the present disclosure may be applied to at least one of the various chambers c1, c2, and c3 that are used for the temperature load test.

The test chamber c1 may include sockets in which semiconductor devices are mounted therein. The semiconductor devices may be electrically connected to a test unit in a state where the semiconductor devices have been mounted in the respective sockets. The test unit may send or receive signals to or from each of the semiconductor devices to which the test unit are electrically connected, and evaluate the performance of the semiconductor device.

An internal space of the test chamber c1 may be set to a predetermined temperature atmosphere as needed in order to test whether the semiconductor device operates appropriately even in a predetermined temperature environment. This temperature atmosphere may be set according to a need of the user. For example, an internal temperature of the test chamber c1 may be set to a specific range in a range from 150 degrees to −70 degrees (Celsius).

The soak chamber c2 may be a chamber in which the semiconductor device is aged before the semiconductor device is exposed to the temperature atmosphere of the test chamber c1. The semiconductor device may be prepared to be exposed to the temperature of the test chamber c1 during a predetermined period of time inside the soak chamber c2.

The soak chamber c2 may include a gate which is formed on one side and through which the semiconductor device is introduced from an external space, and a gate which his formed on the other side and through which the semiconductor device is transported to the test chamber c1. The gate may include configurations for maintaining a temperature atmosphere of an internal space of the soak chamber c2 and/or the test chamber c1.

The de-soak chamber c3 may be a chamber in which the semiconductor device is aged to return to a room temperature after the test ends. The semiconductor device may be prepared to be taken out to the outside during a predetermined period of time inside the de-soak chamber c3.

The de-soak chamber c3 may include a gate which is formed on one side and through which the semiconductor device is taken out to an external space, and a gate which is formed on the other side and through which the semiconductor device is transported from the test chamber c1. The gate may include configurations for maintaining a temperature atmosphere of an internal space of the de-soak chamber c3 and/or the test chamber c1.

The transport unit according to one embodiment of the present disclosure is installed in the chambers c1, c2, and c3 described above, and may transfer the semiconductor device itself or a carrier having the semiconductor device loaded thereinto between the chambers c1, c2, and c3.

in this case, the carrier may be any type of unit formed to be able to load a semiconductor device. For example, the carrier may be a test tray capable of loading a plurality of semiconductor devices. The test tray may include a plurality of inserts corresponding to sockets, and each insert may be formed to be able to load a semiconductor device. Alternatively, for example, the carrier may be an insert for an HBM only formed in consideration of a fine pitch and vulnerability to damage of the HBM so that the carrier can load the HBM. In this case, one or more HBMs may be loaded into the carrier, and the fine pins of the HBM may be electrically connected to terminals formed in the carrier in which the HBM is loaded into the carrier. Similarly, the carrier may be an insert formed to be able to load each of individual DIEs constituting the HBM. Similarly, in this case, fine pins or bumps of the loaded DIE may be electrically connected to the terminals of the carrier in a state where the DIE is loaded into the carrier.

Hereinafter, an example in which the transport unit according to the embodiment of the present disclosure picks up, places, and transports a test tray will be described, but the present disclosure is not necessarily limited to such an embodiment. Accordingly, a holding unit that holds a semiconductor device or a carrier according to an embodiment of the present disclosure may be provided in various ways corresponding to a holding target.

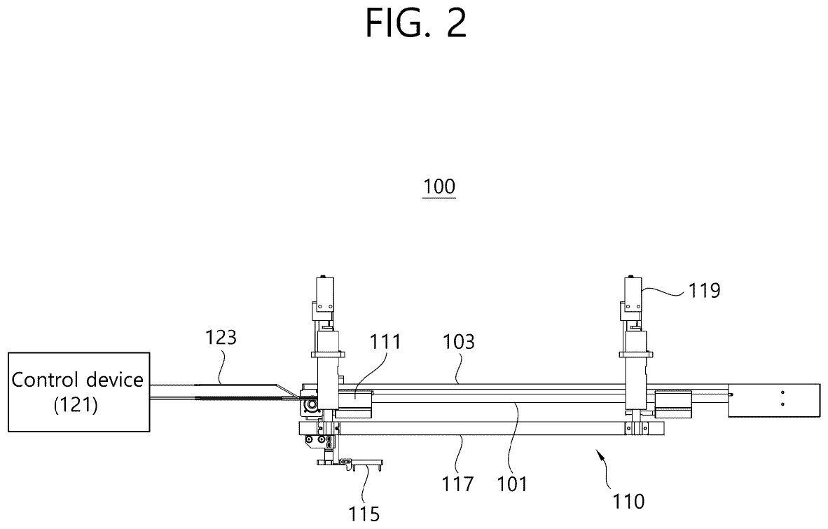

Hereinafter, a semiconductor device transport unit 100 according to an embodiment of the present disclosure will be described with reference to FIG. 2. FIG. 2 is a diagram illustrating the semiconductor device transport unit according to the embodiment of the present disclosure.

As illustrated in FIG. 2, the semiconductor device transport unit 100 according to one embodiment of the present disclosure may include a transport shaft 101, a moving holder 110, and temperature adjusters 121 and 123.

The transport shaft 101 may be an axial member disposed in the internal space of the chamber and extended to correspond to a transport direction of the semiconductor device. The transport shaft 101 may be extended along a movement path of the moving holder 110 inside the chamber.

The moving holder 110 may be a unit that is mounted on the transport shaft 101 with an allowable spacing, and picks up a test tray and transports the test tray to the target position. In this case, the allowable spacing may be a design tolerance and may be set to a tolerance of about 1/10 to 5/100. The moving holder 110 may have various configurations that can transport the carrier along the transport direction and place the carrier at the target position.

The temperature adjuster 121 or 123 may be a module for securing various temperature compatibility for the transport unit 100. The temperature adjuster 121 or 123 may prevent the moving holder 110 from being fixed to the transport shaft 101 in the temperature atmosphere inside the chamber.

The temperature adjuster 121 or 123 may prevent the moving holder 110 from being fixed to the transport shaft 101 by adjusting a temperature of the transport shaft 101 and/or the moving holder 110. The temperature adjuster 121 or 123 may include a control device 121 and a heating wire 123. The temperature adjuster 121 or 123 may exchange heat with the transport shaft 101 and/or the moving holder 110 to secure a minimum spacing between the transport shaft 101 and the moving holder 110 that does not interfere with the movement of the moving holder 110.

The control device 121 can be connected to the heating wire 123 to control the heating wire 123. The heating wire 123 may be heated to a required temperature according to a control signal of the control device 121. The heating wire 123 may be extended by a predetermined length into the transport shaft 101. To this end, the transport shaft 101 may have an accommodation groove for accommodating the heating wire 123. The accommodation groove may be formed along a central axis of the transport shaft 101 so that heat exchange with the heating wire 123 can be uniformly performed at each part.

The heating wire 123 includes one end inserted into the accommodation groove, and the one end may be extended by a predetermined length along the transport direction inside the transport shaft 101. The heating wire 123 includes the other end that protrudes to the outside of the transport shaft 101, and a protruding portion may be mounted on configurations that can interact with the control device 121.

Hereinafter, for the convenience of description, a case where a thermal expansion/contraction rate of the moving holder 110 is higher than that of the transport shaft 101 will be described as an example. Respective configurations/situations can be opposite to such a case when the thermal expansion/contraction rate of the moving holder 110 is lower than that of the transport shaft 101, and repeated description thereof will be omitted.

In the case where the thermal expansion/contraction rate of the moving holder 110 is higher than that of the transport shaft 101, there is a likelihood that the moving holder 110 may become fixed to the transport shaft 101 due to excessive contraction of the moving holder 110 in a situation of a low-temperature condition.

In the temperature adjuster 121 or 123, in order to prevent this situation, the heating wire 123 may be heated so that the transport shaft 101 is heated. In this case, the moving holder 110 may be indirectly heated due to heat from the heated transport shaft 101.

The temperature adjuster 121 or 123 makes it possible to reduce a degree of thermal deformation of the transport shaft 101 and the moving holder 110 compared to a case where the transport shaft 101 and the moving holder 110 are exposed to the temperature atmosphere inside the chamber without protection. Ideally, the temperature adjuster 121 or 123 can transfer heat to the transport shaft 101 and the moving holder 110 so that a spacing between the transport shaft 101 and the moving holder 110 is similar to that under a room temperature condition.

Meanwhile, in the situation of the low temperature condition, not only heat contraction but also condensation, frost, or the like may be formed between the transport shaft 101 and the moving holder 110 to hinder forward and backward movements of the moving holder 110. According to one embodiment of the present disclosure, since the moving holder 110 and the transport shaft 101 are heated, condensation and frost can be prevented from being formed on surfaces of the moving holder 110 and the transport shaft 101. Therefore, in this case, it is possible to secure good transport performance of the moving holder 110 according to one embodiment of the present disclosure.

Continuing the description with reference to FIG. 2, the transport unit 100 may include a mounting frame 103 for fixing positions of other components in the transport unit 100 inside the chamber. The mounting frame 103 is fixed to an inner wall of the chamber and may support other components included in the transport unit 100.

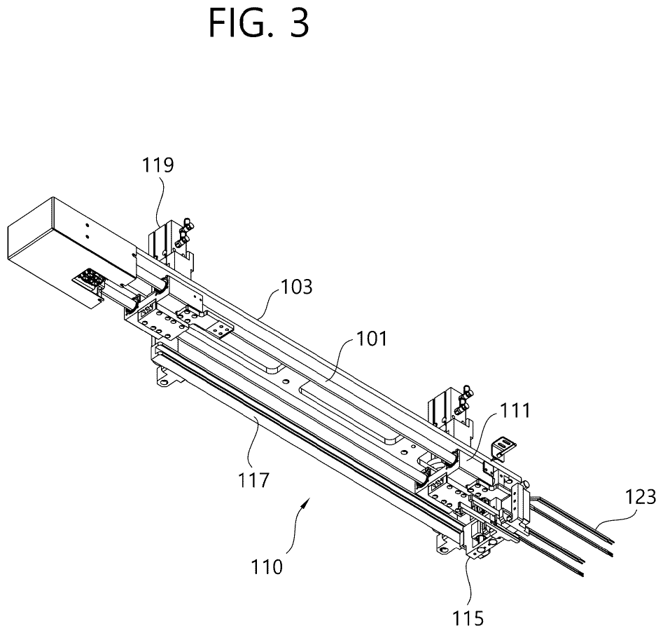

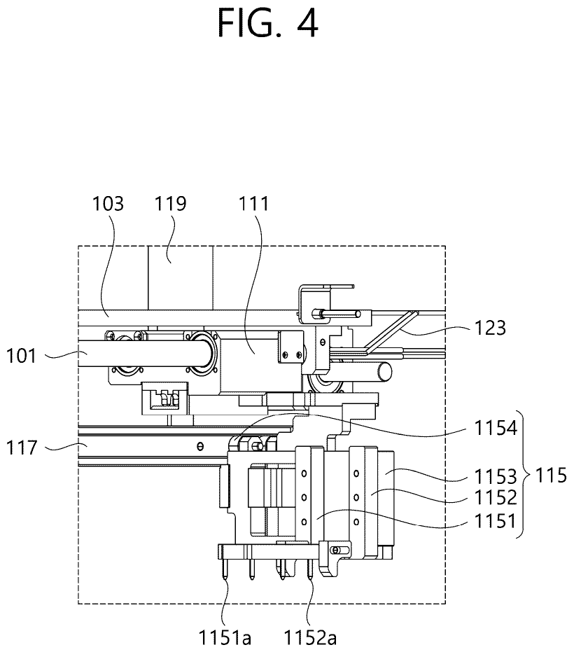

Hereinafter, the moving holder 110 according to an embodiment of the present disclosure will be described in detail with reference to FIGS. 3 and 4. FIG. 3 is a view illustrating the transport unit according to the embodiment of the present disclosure when viewed from a different angle from that in FIG. 2. Further, FIG. 4 is an enlarged view of the moving holder portion in the transport unit according to the embodiment of the present disclosure.

As confirmed from FIGS. 3 and 4, the transport shaft 101 according to the embodiment of the present disclosure is included as a pair, and each of the transport shafts 101 may extend substantially in a straight line along the transport direction. The moving holder 110 is mounted on the pair of transport shafts 101 and can be moved forward and backward in a state where both sides of the moving holder 110 are supported by the transport shafts 101.

The description will continue with reference to FIGS. 3 and 4. The moving holder 110 according to the embodiment of the present disclosure may include a moving block 111, a holding block 115, a guide rail 117, and elevating actuators 119.

The moving block 111 may be a block that is mounted on a pair of transport shafts 101 and moves forward and backward along the pair of transport shafts 101. In a body of the moving block 111, through holes in which the respective transport shafts 101 are accommodated may be formed. The pair of through holes may be formed at an interval corresponding to the interval of the transport shafts 101, and central axis thereof may be located on the same plane.

The forward and backward movements of the moving block 111 may be implemented by one of various driving units of the related art, and the driving unit may be controlled by the control device 121 or a control unit that controls the transport unit 100.

The holding block 115 is located on one side of the moving block 111, and a relative distance from the moving block 111 can be adjusted. For convenience of description, the holding block 115 is expressed as being located under the moving block 111, but “under” may also be expressed as “over”, “to the left”, “to the right”, or the like depending on an installation direction of the transport unit 100.

The holding block 115 may be coupled to the moving block 111 so that holding block 115 can be raised or lowered with respect to the moving block 111, and may be configured to hold a test tray located under the holding block 115. This holding block 115 may include a block housing 1153, a first holding frame 1151, a second holding frame 1152, and a roller 1154.

For example, the holding block 115 may be configured such that each of the first holding frame 1151 and the second holding frame 1152 carries one test tray. Alternatively, as another example, the holding block 115 may be configured such that the first holding frame 1151 and the second holding frame 1152 hold one test tray together.

The block housing 1153 may be a housing coupled to the moving block 111 so that the housing can be raised or lowered.

The first holding frame 1151 may be a frame coupled to the block housing 1153. At least one hook 1151a may protrude downward from the first holding frame 1151. The hook 1151a included in the first holding frame 1151 is referred to as a first hook 1151a for convenience in order to distinguish the hook 1151a from a hook 1152a of the second holding frame 1152.

The second holding frame 1152 may be a frame coupled to the block housing 1153 to be located on the side of the first holding frame 1151. At least one hook 1152a may protrude downward from the second holding frame 1152. The hook 1152a included in the second holding frame 1152 is referred to as a second hook 1152a for convenience in order to distinguish the hook 1152a from the first hook 1151a.

The first holding frame 1151 and the second holding frame 1152 may be coupled to the block housing 1153 so that a relative distance between the first holding frame 1151 and the second holding frame 1152 can be adjusted. A driving unit for adjusting a spacing between the first holding frame 1151 and the second holding frame 1152 may be provided as one of various driving units of the related art. In addition, this driving unit may be controlled by the control device 121 or a control unit that controls the transport unit 100.

The roller 1154 may be disposed on a side of the block housing 1153 to support the transport of the holding block 115. The roller 1154 is coupled to one side of the block housing 1153 and inserted the guide rail 117 so that the roller 1154 can move forward and backward along the guide rail 117.

The guide rail 117 may be a rail that supports the movement of the holding block 115. The roller 1154 may be inserted into the guide rail 117. The guide rail 117 may be extended to correspond to a direction in which the transport shaft 101 is extended. For example, the guide rail 117 may be extended along an axis parallel to the central axis of the transport shaft 101.

The holding block 115 may be coupled to the moving block 111 so that holding block 115 can be moved forward or backward with the movement of the moving block 111. In this forward and backward movement process, the holding block 115 may be supported by the guide rail 117 so that shaking may be minimized in the forward and backward movement process.

Meanwhile, each of a front end and a rear end of the guide rail 117 may be coupled to the elevating actuators 119. The elevating actuators 119 may be coupled to the mounting frame 103 and/or the inner wall of the chamber so that a position of the elevating actuator 119 is fixed, and may be implemented in various configurations in which a length of a lower end of the elevating actuator 119 can be extended downward. The elevating actuator 119 may be controlled by the control device 121 or the control unit that controls the transport unit 100.

A side wall portion of the guide rail 117 may be coupled to the lower end of each of the elevating actuators 119. This makes it possible for the guide rail 117 to be raised or lowered when the lower ends of the elevating actuators 119 are lowered or raised.

When the guide rail 117 is raised or lowered, the roller 1154 inserted into the guide rail 117 can be raised or lowered together. When the roller 1154 is raised or lowered, the holding block 115 can also be raised or lowered. However, the present disclosure is not limited to this embodiment, and the holding block 115 is raised or lowered by the elevating actuators 119, and the guide rail 117 can also be raised or lowered.

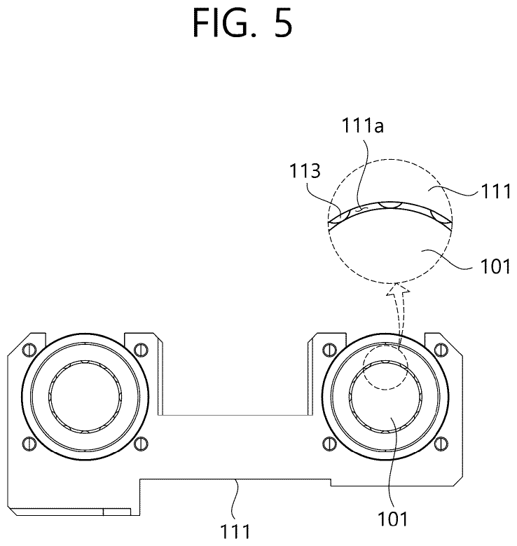

Hereinafter, a coupling relationship between the transport shaft 101 and the moving block 111 according to one embodiment of the present disclosure will be described in detail with reference to FIG. 5. FIG. 5 is a diagram illustrating the transport shaft and the moving block according to the embodiment of the present disclosure when viewed from the front.

As illustrated in FIG. 5, the moving holder 110 may include a plurality of balls 113 mounted inside the moving block 111 and protruding into the through hole 111a. Accordingly, the moving block 111 may function like a ball bushing that moves along the axis of the transport shaft 101.

The plurality of balls 113 may be disposed at certain intervals inside the through hole. More specifically, the plurality of balls 113 may be disposed on a side wall of the through hole 111a at an interval at which a length of a circumference of the through hole 111a is evenly divided. The transport shaft 101 inserted the through hole 111a may be supported inside the through hole 111a by the plurality of balls 113. The transport shaft 101 may have a diameter slightly smaller than the through hole 111a in consideration of sizes of the plurality of balls 113. Further, this difference in diameter can define the above-described allowable spacing.

The plurality of balls 113 make it possible for the transport shaft 101 to come into point contact with the balls 113 without coming into contact with a surface of the moving block 111. Thus, it is possible to minimize a contact area between the moving holder 110 and the transport shaft 101, and to minimize friction between the moving holder 110 and the transport shaft 101.

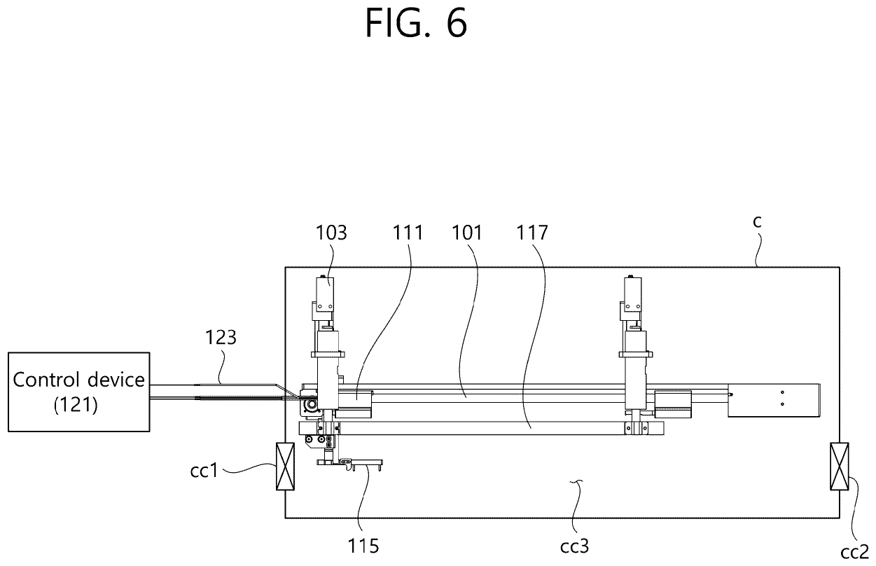

Hereinafter, an example in which the transport unit according to the embodiment of the present disclosure is installed inside the chamber will be described with reference to FIG. 6. FIG. 6 is a conceptual drawing illustrating an example in which the semiconductor device transport unit according to the embodiment of the present disclosure is installed inside the chamber.

Referring to FIG. 6, the chamber c may be the soak chamber or de-soak chamber described above.

The chamber c may be extended in a vertical direction in FIG. 6, and a test tray may be transported along a direction in which chamber c is extended.

The chamber c may form an internal space cc3 through which the semiconductor device passes, and may include a chamber housing that divides the external space from the internal space cc3. The chamber housing may form an inner wall of the chamber c and may be coupled to the mounting frame 103.

A first gate cc1 that divides the external space from the internal space cc3 may be formed on one side of the chamber c. On the other hand, a second gate cc2 that separates the internal space cc3 and an internal space of another chamber may be formed on the other side of the chamber c. In this case, the other external chamber may be a test chamber.

The transport shaft 101 may be disposed in a straight line between the first gate cc1 and the second gate cc2. The mounting frame 103 may be coupled to the inner wall of the chamber c so that the transport shaft 101 and the moving holder 110 are supported.

The transport shaft 101 may be installed so that a front end thereof is as close as possible to the first gate cc1. The heating wire 123 may be inserted into the accommodation groove through the front end of the transport shaft 101. The exposed other end of the heating wire 123 may protrude to the first gate cc1 from the front end of the transport shaft 101.

A position of the heating wire 123 can be advantageous in terms of securing of a space for installing the control device 121 and/or a configuration for temperature adjustment. More specifically, the position of the heating wire 123 can allow the control device 121 and/or the configuration for temperature adjustment to be installed in the external space. Therefore, there is an advantage in that interference with configurations of other chambers does not have to be considered for the position of the heating wire 123, and a configuration for protecting the control device 121 and the like in the temperature atmosphere inside the chamber c can be omitted.

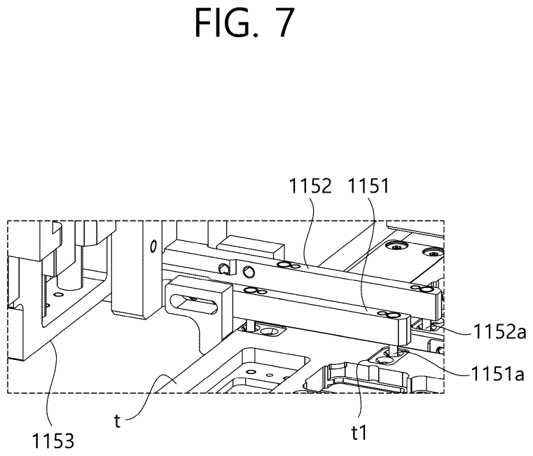

Hereinafter, a method in which the holding block 115 according to the embodiment of the present disclosure picks up a test tray t will be described with reference to FIG. 7. FIG. 7 is a diagram partially illustrating the holding block and the test tray according to the embodiment of the present disclosure.

Hereinafter, a case where the test tray t is transported will be mainly described by way of example in an embodiment of the present disclosure, but the present disclosure is not limited thereto. For example, a groove t1 of the test tray t may be formed in the semiconductor device, a separate member attached thereto, or another type of carrier, and the holding block 115 may transport the semiconductor device and/or the carrier using such a groove t1.

When each of the first holding frame 1151 and the second holding frame 1152 transports one test tray t, the first hook 1151a and the second hook 1152a may be inserted into the grooves t1 of different test trays t in a state where the holding block 115 is lowered. The first hook 1151a and the second hook 1152a may have a shape corresponding to the groove t1 formed in the test tray 1.

In this case, each of the first hook 1151a and the second hook 1152a may hold one test tray 1 using various methods. The first hook 1151a and the second hook 1152a may be provided so that a protruding member (not shown) selectively protrudes from a lower end. The protruding member may protrude om am outward direction (in a direction intersecting a direction in which the groove is extended and/or in a direction intersecting a thickness direction of the test tray) from bodies of the hooks 1151a and 1152a in a state where the hooks 1151a and 1152a are fully inserted into the grooves t1 of the test trays t. The protruding member may support a back surface of the test tray t (a surface that does not face the first and second holding frames) in a state where the protruding member has protruded.

Alternatively, the first holding frame 1151 and the second holding frame 1152 may be formed such that a spacing is adjustable with respect to each other to be able to hold one test tray t. In this case, when the first holding frame 1151 and the second holding frame 1152 maintain an initial spacing, the first hook 1151a and the second hook 1152a may correspond to a plurality of grooves t1 formed in the test tray t.

In a state where the block housing 1153, the first holding frame 1151, and the second holding frame 1152 are lowered, the first hook 1151a and the second hook 1152a can be inserted into the corresponding grooves t1 in the test tray t, respectively.

Then, when the spacing between the first holding frame 1151 and the second holding frame 1152 becomes smaller or larger than the initial spacing, the first hook 1151a and the second hook 1152a may apply forces in opposite directions to side walls of the test tray t. In this state, the test tray t may be held by the holding block 115.

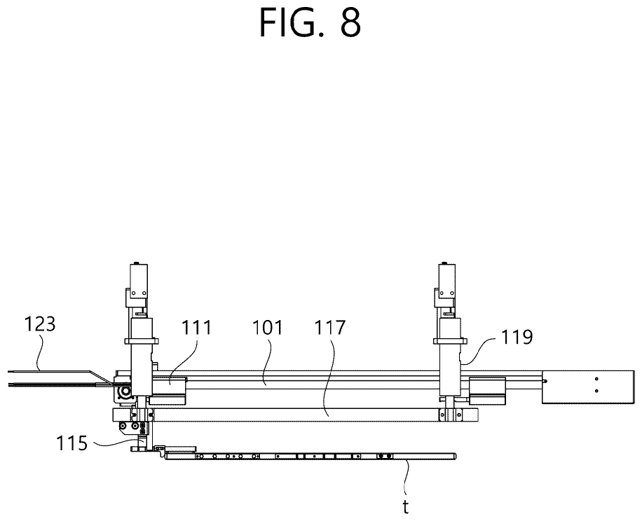

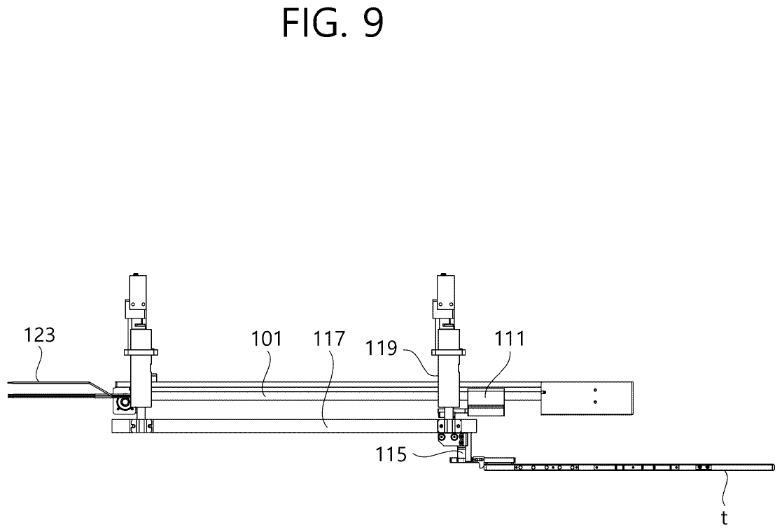

Continuing the description with reference to FIGS. 8 and 9, FIG. 8 is a view illustrating a case where the transport unit according to the embodiment of the present disclosure holds the test tray at an initial position. On the other hand, FIG. 9 is a view illustrating a case where the transport unit according to the embodiment of the present disclosure transports the test tray to a target position.

When the test tray t is transported into the chamber where the transport unit 100 is installed, the test tray t may be located at a position as illustrated in FIG. 8. At an initial position of the test tray t, the groove t1 of the test tray t may be located directly under the hooks 1151a and 1152a of the holding block 115. When the transport of the test tray t starts, the holding block 115 may be lowered to hold the test tray t as described above.

Thereafter, when the moving block 111 moves forward to a position of FIG. 9, the test tray t maybe transported to the target position. In a process in which the moving block 111 moves, since the holding block 115 is supported by the guide rail 117, the shaking of the test tray t in a height direction can be minimized.

Meanwhile, referring to FIG. 6 together for a moment, in a state where the moving block 111 fully moves forward, the test tray t may be moved from the internal space cc3 of the chamber c to the external space. In this state, the test tray t may be picked up by a transport unit, a transfer, or the like of another chamber and moved to another device.

Hereinafter, a semiconductor device transport unit according to another embodiment of the present disclosure will be described based on the above description. Description of portions that are the same as or similar to the above-described embodiment will be omitted in order to avoid repeated description, and differences will be mainly described.

Although the heating wire 123 of the temperature adjuster is inserted into the transport shaft 101 in the above-described embodiment, the heating wire 123 may be mounted on the moving holder 110 in the present embodiment. For example, in the present embodiment, the heating wire 123 may be mounted inside the moving block 111. In the present embodiment, the degree of thermal deformation of the transport shaft 101 can be reduced by heat exchange with the moving block 111 of which the temperature has been adjusted by the heating wire 123.

A case where the heating wire 123 is mounted on the moving block 111 rather than the transport shaft 101 has been described above in the other embodiment of the present disclosure, but the semiconductor device transport unit according to the other embodiment of the present disclosure is not limited to such an embodiment.

For example, in the semiconductor device transport unit according to the other embodiment of the present disclosure, the heating wire 123 may be installed in both the transport shaft 101 and the moving block 111.

Those skilled in the art to which the present disclosure pertains will understand that the present disclosure can be implemented in other specific forms without departing from the technical spirit or essential characteristics of the present disclosure. Therefore, it should be understood that the embodiments described above are illustrative in all respects and not limited. The scope of the present disclosure is indicated by the claims to be described below rather than the detailed description, and all changes or modifications derived from the meaning and scope of the claims and equivalent concepts thereof should be construed as being included in the scope of the present disclosure.

### DESCRIPTION OF REFERENCE SIGNS

100: Transport unit
101: Transport shaft
103: Mounting frame
110: Moving holder
111: Moving block
111a: Through hole
113: Ball
115: Holding block
1151, 1152: Holding frame
1151a, 1152a: Hook
1153: Block housing
1154: Roller
117: Guide rail
119: Elevating actuator
121: Control device
123: Heating wire
c: Chamber
c1: Test chamber
c2: Soak chamber
c3: De-soak chamber
cc1: First gate
cc2: Second gate
cc3: Internal space
t: Test tray
t1: Groove

What is claimed is:

1. A semiconductor device transport unit installed in a chamber providing a temperature atmosphere set as needed, the semiconductor device transport unit comprising:
a transport shaft disposed in an internal space formed by the chamber and extended along a transport direction of the semiconductor device;
a moving holder mounted on the transport shaft with an allowable spacing and configured to transport a carrier having the semiconductor device loaded thereinto along the transport direction; and
a temperature adjuster configured to adjust a temperature of at least one of the moving holder and the transport shaft so that the moving holder is prevented from being fixed to the transport shaft in the temperature atmosphere.

2. The semiconductor device transport unit of claim 1, wherein the temperature adjuster adjusts the temperature of the moving holder and the transport shaft so that a degree of thermal deformation of the moving holder and the transport shaft due to the temperature atmosphere is reduced.

3. The semiconductor device transport unit of claim 2, wherein the temperature adjuster includes a heating wire formed to transfer heat to the transport shaft and extended by a predetermined length along the transport direction.

4. The semiconductor device transport unit of claim 3, wherein the heating wire includes
one end part inserted into the transport shaft and extended by the predetermined length along the transport direction, and
the other end part protruding to the outside of the transport shaft and connected to a control device.

5. The semiconductor device transport unit of claim 4, wherein the chamber includes
a first gate configured to divide an external space from the internal space, and
a second gate configured to divide the internal space from a space formed by an external chamber for performing a process for the semiconductor device,
the transport shaft is extended between the first gate and the second gate, and
the other end part of the heating wire protrudes to the first gate from the transport shaft.

6. The semiconductor device transport unit of claim 1, wherein the temperature atmosphere is set to a temperature equal to or lower than a room temperature, and the temperature adjuster transfers heat to the transport shaft and the moving holder to prevent at least one of condensation and frost from being formed at the allowable spacing.

7. The semiconductor device transport unit of claim 1, wherein the moving holder includes
a moving block having a through hole into which the transport shaft is inserted; and
a ball installed inside the moving block to protrude into the through hole and configured to support the transport shaft at a position inside the through hole.

8. The semiconductor device transport unit of claim 7, wherein a plurality of the balls protrude into the through hole to prevent the transport shaft from coming into contact with the moving block.

9. The semiconductor device transport unit of claim 1, wherein the moving holder includes
a moving block configured to move forward and backward on the transport shaft; and
a holding block formed under the moving block to be able to be raised or lowered with respect to the moving block and configured to hold the carrier.

10. The semiconductor device transport unit of claim 9, wherein the moving holder further includes a guide rail extended along a direction in which the transport shaft is extended, raised or lowered together with the holding block, and configured to support the holding block moving forward and backward along the moving block in a process in which the moving block moves forward and backward on the transport shaft.

11. The semiconductor device transport unit of claim 9, wherein the holding block includes
a first holding frame having a hook which is protruding downward and inserted into a groove of the carrier in a lowered state, and
a second holding frame formed that a spacing with the first holding frame is adjustable, and having another hook which is protruding downward and inserted into another groove of the carrier in a lowered state.

12. The semiconductor device transport unit of claim 1, wherein the carrier loads an HBM or a DIE forming the HBM as the semiconductor device, and includes terminal electrically connected to the loaded semiconductor device.

13. A chamber for providing a temperature atmosphere set as needed and performing a process for a semiconductor device, the chamber comprising:
a chamber housing configured to form an internal space through which the semiconductor device passes; and
a transport unit installed to transport the semiconductor device, and
the transport unit includes
a transport shaft disposed in the internal space and extended along a transport direction of the semiconductor device,
a moving holder mounted on the transport shaft with an allowable spacing and configured to transport a carrier having the semiconductor device loaded thereinto along the transport direction; and
a temperature adjuster configured to adjust a temperature of at least one of the moving holder and the transport shaft so that the moving holder is prevented from being fixed to the transport shaft in the temperature atmosphere.
